(19) United States
(12) Patent Application Publication
(10) Pub. No.: US 2025/0155484 A1
(43) Pub. Date: May 15, 2025

(54) METHOD AND APPARATUS WITH FREQUENCY CHARACTERISTICS ANALYSIS OF PRINTED CIRCUIT BOARD

(71) Applicant: Samsung Electronics Co., Ltd., Suwon-si (KR)

(72) Inventors: Doyun KIM, Suwon-si (KR); Jaemin PARK, Suwon-si (KR); Youngmin OH, Suwon-si (KR); Bosun HWANG, Suwon-si (KR)

(73) Assignee: Samsung Electronics Co., Ltd., Suwon-si (KR)

(21) Appl. No.: 18/945,874

(22) Filed: Nov. 13, 2024

(30) Foreign Application Priority Data
Nov. 13, 2023 (KR) 10-2023-0156424
Jul. 11, 2024 (KR) 10-2024-0091978

(51) Int. Cl. G01R 27/26

(52) U.S. Cl. CPC G01R 27/2611

(57) ABSTRACT

An apparatus and method for analyzing a frequency characteristics of a substrate are provided, through the steps of tokenizing a trace of a substrate into a graph, generating a representation vector from the tokens of the graph, and analyzing a frequency characteristics of the substrate based on the representation vector.

### CROSS-REFERENCE TO RELATED APPLICATION

This application claims priority to and the benefit under 35 USC § 119 (a) of Korean Patent Application No. 10-2023-0156424 filed in the Korean Intellectual Property Office on Nov. 13, 2023, and Korean Patent Application No. 10-2024-0091978 filed in the Korean Intellectual Property Office on Jul. 11, 2024, the entire contents of which are incorporated herein by reference.

### BACKGROUND

### 1. Field

This description relates to a method and apparatus for analyzing frequency characteristics of a substrate.

### 2. Related Art

Semiconductor chips (controller, memory, etc.) are mounted on a substrate and a high-speed digital communication is performed through the chips on the substrate. In the high-speed communication between the chips, signal defects may occur depending on characteristics of a channel connecting the chips, and the characteristics of the channel may vary depending on the shape of the trace on the substrate.

The integrity of a signal transmitted through the substrate can be analyzed from the layer information and material property information of the substrate by a program that designs the substrate (e.g., SIwave). However, as the frequency range of the analysis target increases (e.g., over 15 GHZ) and the design complexity of the substrate increases, the number of operations required for the substrate design program have increased and accordingly, the time required for the analysis have increased significantly.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an apparatus for determining frequency characteristics of a substrate includes: one or more processors and a memory, wherein the memory stores instructions causing the one or more processors to perform a process including: transforming a trace of the substrate to a graph and tokenizing the graph into tokens; generating representation vectors from the tokens; and determining the frequency characteristics based on the representation vectors.

The transforming the trace of the substrate to the graph and tokenizing the graph may include: generating the graph to represent a 4-port network included in the substrate; and tokenizing the graph into a sequence of the tokens.

The 4-port network may include two components and the trace connecting the two components, and the generating the graph representing the 4-port network included in the substrate may include generating edges respectively corresponding to segments included in the trace and connecting ends of the edges at corresponding nodes.

The tokenizing the graph into the sequence of tokens may include: extracting features of the segments from trace data of the substrate; generating positional information by performing positional encoding on the edges; and generating the tokens respectively corresponding to the edges based on the features and positional information of the corresponding segments.

The generating the tokens respectively corresponding to the edges based on the features of the segment and the positional information may include: performing linear projection on the features and positional information of the segments using a linear layer of a neural network.

Each segment may include corresponding coordinate information thereof the segment and length information thereof.

The determining the frequency characteristics based on the representation vectors may include: predicting scattering parameters of a 4-port network included in the substrate as the frequency characteristics of the substrate.

The predicting the scattering parameters of the 4-port network included in the substrate as the frequency characteristics of the substrate may include: predicting the scattering parameters by using representation vectors respectively corresponding to segments connected to each component of the 4-port network among segments included in the trace as an input.

The predicting the scattering parameters by using a representation vector corresponding to a segment connected to each component of the 4-port network among a plurality of segments included in the trace as an input may include: outputting a first graph image corresponding to a reflection parameter of the scattering parameters by using a first representation vector corresponding to a first segment connected to a first port of a first component of the 4-port network as a first input; outputting a second graph image corresponding to a transmission parameter of the scattering parameters by using a second representation vector corresponding to a second segment connected to a second port of a second component of the 4-port network as a second input; outputting a third graph image corresponding to a near-end crosstalk parameter of the scattering parameters by using a third representation vector corresponding to a third segment connected to a third port of the first component of the 4-port network as a third input; or outputting a fourth graph image corresponding to a far-end crosstalk parameter of the scattering parameters by using a fourth representation vector corresponding to a fourth segment connected to a fourth port of the second component of the 4-port network as a fourth input.

The process may further include: transferring one or more of the graph images to a simulator for signal integrity analysis of the substrate.

In another general aspect, a method for predicting frequency characteristics of a substrate is performed by one or more processors and includes: tokenizing a graph representing a trace of the substrate into a sequence of tokens; generating a set of representation vectors by encoding the sequence of tokens; and predicting the frequency characteristics based on the set of representation vectors.

The tokenizing the graph representing the trace of the substrate into the sequence of tokens may include: generating geometrical information of segments included in the trace from trace data of the substrate; generating topology information of the segments by performing positional encoding on edges in the graph; and generating tokens corresponding to the edges based on the geometrical information and the topology information.

The generating the set of representation vectors by encoding the sequence of tokens may include: encoding the sequence of tokens into the set of representation vectors through encoder layers of a neural network.

The representation vectors in the set of representation vectors may be embeddings of respective segments included in the trace, and tokens included in the sequence of tokens may respectively correspond to the segments.

The predicting the frequency characteristics based on the set of representation vectors may include predicting scattering parameters of a 4-port network on or in the substrate as the frequency characteristics using a trained prediction network.

The predicting scattering parameters of the 4-port network on or in the substrate as the frequency characteristics using the trained prediction network includes: inputting representation vectors corresponding to segments connected to each component of the 4-port network to the trained prediction network; and predicting graph images respectively corresponding to each of a reflection parameter, a transmission parameter, a near-end crosstalk parameter, and a far-end crosstalk parameter of the scattering parameters using the trained prediction network.

The method may further include: transmitting predicted graph images respectively corresponding to the reflection parameter, the transmission parameter, the near-end crosstalk parameter; and the far-end crosstalk parameter to a simulator for signal integrity analysis of the substrate.

In another general aspect, an apparatus for determining frequency characteristics of a substrate includes: one or more processors and a memory, wherein the memory stores instructions configured to cause the one or more processors to perform a process including: transforming a trace of the substrate into a graph; tokenizing the graph into a sequence of tokens using a linear layer of neural network; generating a set of representation vectors from the sequence of tokens using a encoder of the neural network; and using a prediction network to determine the frequency characteristics from the set of representation vectors by using a prediction network.

The process may further include: training the linear layer, the encoder, and the prediction network using trace data of a labeled substrate and a labeled graph image matched to the trace data, wherein the labeled substrate is a substrate of which training frequency characteristics have been determined in advance as a ground truth.

The training the linear layer, the encoder, and the prediction network using trace data of the labeled substrate and graph images matched to the trace data may include: tokenizing a graph representing traces of the labeled substrate using the linear layer; generating an embedding from tokenized graphs using the encoder; predicting a training graph image of scattering parameters of the labeled substrate from the embedding using the prediction network; and updating the linear layer, the encoder, and the prediction network based on calculation of a loss function using the predicted training graph image and the labeled graph image. Other features and aspects will be apparent from the following detailed description, the drawings, and the claims.

### BRIEF DESCRIPTION OF THE DRAWINGS

FIG. 1 illustrates a cross-sectional view of structure of a circuit for high-speed signal transmission between components on a substrate according to one or more embodiments.

FIG. 2 illustrates a modeling device according to one or more embodiments.

FIG. 3 illustrates a substrate modeling method according to one or more embodiments.

FIG. 4 illustrates a portion of the trace data of a substrate according to one or more embodiments.

FIG. 5 illustrates a graph tokenizer according to one or more embodiments.

FIG. 6 illustrates a method for tokenizing a graph representing a trace according to one or more embodiments.

FIG. 7 illustrates a method for tokenizing a graph representing a trace according to one or more embodiments.

FIG. 8 illustrates the structure of an encoder according to one or more embodiments.

FIG. 9 illustrates the structure of a prediction network according to one or more embodiments.

FIG. 10 illustrates the training steps of a modeling device according to one or more embodiments.

FIG. 11 illustrates a neural network according to one or more embodiments.

FIG. 12 illustrates a modeling device according to another embodiment.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

The artificial intelligence model (AI model) of the present disclosure is a machine learning model that learns at least one task (task) and can be implemented as a computer program executed by a processor. The task learned by the AI model may refer to a problem to be solved through machine learning or a work to be performed through machine learning. AI models may be implemented as computer programs that run on computing devices, downloaded over a network, or sold in a product form. Alternatively, the AI model may be connected to various devices through a network. Also, the AI model may be interoperable with various devices through a network.

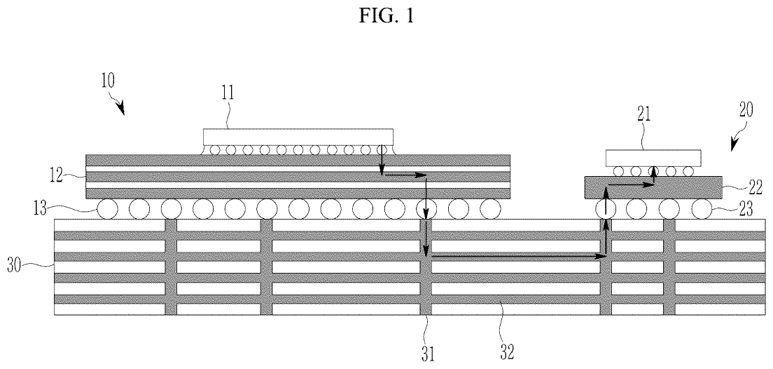

FIG. 1 illustrates a cross-sectional view of structure of a circuit for high-speed signal transmission between components on a substrate, according to one or more embodiments.

In some embodiments, components such as controller 10, memory 20, etc. are mounted on a substrate 30 and may transmit/receive signals at high speed through a trace 31 of the substrate 30. The trace 31 may be arranged in a layer of the substrate 30 and the substrate 30 may include multiple layers. The substrate 30 may be, for example, a printed circuit board (PCB), an integrated circuit substrate (IC substrate), and/or a package substrate, as non-limiting examples.

Referring to FIG. 1, the controller 10 may send a signal to the memory 20 via the substrate 30. Specifically, a signal transmitted from a controller chip 11 of the controller 10 may be transmitted to the substrate 30 through a controller package 12 and a package ball 13 and then transmitted to the memory 20 through the trace 31 and a via 32 of the substrate 30. The signal of the controller 10 transmitted through the substrate 30 may be transmitted to a memory chip 21 through the package ball 23 and a memory package 22 of the memory 20.

In some embodiments, a modeling device (e.g., a device with a neural network model) may generate an embedding (e.g., an embedding vector) that represents a trace connecting two components (e.g., processors, memories, etc.) on a substrate; the modeling device may predict frequency characteristics of the substrate by using the embedding of the trace. The predicted frequency characteristics may be used for modeling the substrate on which the components are mounted. In addition, the substrate model generated through the modeling may be used for signal integrity analysis. For example, frequency response functions/maps may be inferred.

Alternatively, the modeling device may generate an embedding representing connections between components on and/or within a chip (or a board with chips) based on on-chip data of the chip and predict the frequency characteristics of the connections between the components by using the connections embedding. Described below, are methods for transforming the trace of the substrate into a graph based on trace data of the substrate and predicting the frequency characteristics of the substrate using the transformed graph, but this description is not limited thereto, and modeling devices of this description may also be used to predict the frequency characteristics of the connections between the components within a computer chip based on the on-chip data of the computer chip.

In some embodiments, the modeling device may generate a graph based on the trace data of the trace to generate embeddings that represent the trace of the substrate and generate the embeddings that represent the trace based on tokens of the generated graph. Afterwards, the modeling device may predict the frequency characteristics of the substrate based on the embeddings.

In some embodiments, the modeling device may infer scattering parameters (S parameters) of a 4-port network based on representation vectors (that is, embedding) of the traces to predict the frequency characteristics of the substrate. Below, the method by which the modeling device generates the embeddings of the traces and the method by which the modeling device infers the S parameters based on the embeddings of the traces are described in detail.

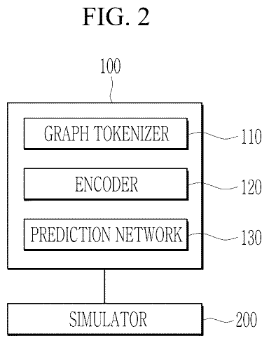

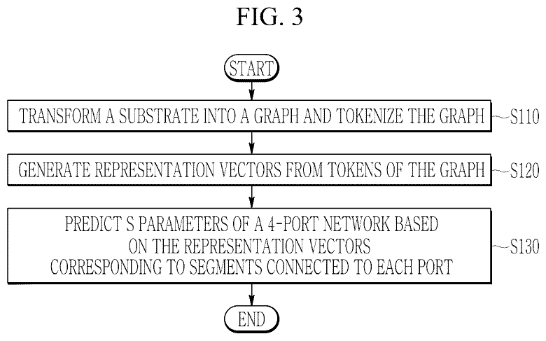

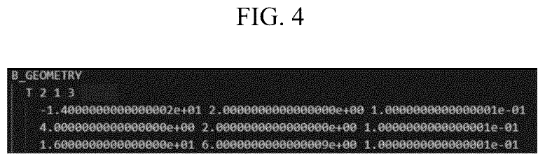

FIG. 2 illustrates a modeling device according to one or more embodiments, FIG. 3 illustrates a substrate modeling method according to one or more embodiments, and FIG. 4 illustrates a portion of trace data of a substrate according to one or more embodiments.

Referring to FIG. 2, a modeling device 100 according to one or more embodiments may include a graph tokenizer 110, an encoder 120, and a prediction network 130. In some embodiments, the modeling device 100 may generate an embedding representing a substrate using a neural network model to predict, from trace data of the substrate, frequency characteristics of the substrate from the generated embedding.

Referring to FIG. 2 and FIG. 3, at step S110, the graph tokenizer 110 may transform a representation of a substrate into a graph using the trace data (e.g., trace data used for manufacturing the substrate) and tokenize the generated graph. Components such as processors, ICs, and memory chips may be placed on the substrate and the components may be connected to each other via the traces on the substrate.

As noted, in some embodiments, the graph tokenizer 110 may generate a graph based on the trace data of the substrate. In some embodiments, the trace data may include design information of the substrate. For example, the trace data may include information about the traces, information about vias, and stack-up information of the substrate (thickness of layers included in the substrate, permittivity of the layers, etc.). The information about the trace may include one or more of: an identifier of a substrate including the trace, an identifier of a layer within the substrate including the trace, the number of segments included in the trace, and information about the segments.

In FIG. 4, “T” indicates that the number region below FIG. 4 is trace data, “2” indicates that the identifier of the substrate containing the trace is 2, “1” indicates that the identifier of the layer containing the trace is 1, and “3” indicates that the trace contains three segments.

The 3×3 number array in FIG. 4 represents coordinate information and thickness (width) of three bend points by three segments included in the trace. The first column of the 3×3 array is a column of bend point x-coordinates, the second column is a column of bend point y-coordinates, and the third column is a column of segment thicknesses. The coordinates of a bend point may represent the position of the bend point on the substrate. The 3×3 array size is a non-limiting example.

The coordinates in a trace's array may be implicitly chained, starting from a start point of the trace. More specifically, when the start point of a trace is predetermined in the trace data, the coordinates of the start point may function as the coordinates of the start point of the first segment (i.e., the trace's first segment's start point is the same as the predetermined start point of the trace); the x-coordinate and y-coordinate of the first bend point in the trace array function as the coordinates of the end point of the first segment. The end point of the first segment may function as the start point of the second segment; the end point of the second segment may be the x-coordinate and y-coordinate of the second bend point in the array, and so forth. Put another way, each point in a trace array may be the end point of a corresponding segment and may also be, implicitly, the start point of the next segment.

In FIG. 4, the first row of the 3×3 array may represent (i) the x-coordinate and y-coordinate of the endpoint and (ii) thickness of the first segment. The second row may represent (i) the x-coordinate and y-coordinate of the endpoint and (ii) thickness of the second segment included in the trace. And, the third row may represent (i) the x-coordinate and y-coordinate of the endpoint and (ii) thickness of the third segment included in the trace.

In some embodiments, the graph tokenizer 110 may transform segments of the trace into graph edges based on the trace data and connect each edge to generate the graph. Connections of edges may become respective nodes of the graph. In the example trace data of FIG. 4, the represented trace includes three segments, and the graph tokenizer 110 may transform the trace of the substrate into a graph having three edges.

In some embodiments, a graph tokenizer 110 may tokenize the graph representing the trace of the substrate into the sequence of tokens. Each token in the sequence may correspond to an edge of the graph (which may represent a corresponding segment of the trace of the substrate). Referring to FIGS. 2 and 3, at step S120, the encoder 120 may encode the sequence of tokens of the graph representing the trace into a set of representation vectors.

In some embodiments, the sequence of tokens generated by the graph tokenizer 110 may be input to the encoder 120 and the encoder 120 may generate the set of representation vectors from the sequence of tokens. In some embodiments, the encoder 120 may process the sequence of input tokens in parallel using multiple encoder layers. For example, the encoder 120 may be an encoder of a transformer model.

In some embodiments, each representation vector in the set of representation vectors may have a one-to-one correspondence relationship with a token in the sequence of tokens. Each representation vector may be an embedding representing a segment corresponding to a token. Additionally, when a specific segment within a trace is connected to a specific port of a component, the representation vector corresponding to that segment may be an embedding representing that port.

Referring to FIGS. 2 and 3, the prediction network 130 may predict (infer) the frequency characteristics of the substrate based on the representation vectors generated by the encoder 120 S130. The prediction network 130 may predict, as the frequency characteristics of the substrate, scattering parameters (S parameters) of a 4-port network consisting of components and traces, as a non-limiting example.

In some embodiments, when each of two components on a substrate have n ports (n>1) and the two components are connected by n traces, the prediction network 130 may predict the S parameters of the 2n-port network (which includes the two components and the traces). For example, when the first component and the second component on a substrate each have two ports that are connected by two respective traces, the first component and the second component may form a 4-port network.

In a non-limiting example discussed below, the first component is assumed to have ports 1 and 3 and the second component is assumed to have ports 2 and 4. The prediction network 130 according to one or more embodiments may predict the S parameters of the 4-port network based on the representation vectors of the trace. The S parameters of the 4-port network may be expressed as Equation 1 below.

$$S = {( {S}_{ij} )}_{i , j = 1 , 2 , 3 , 4} = ( \begin{matrix}{S}_{11} & {S}_{12} & {S}_{13} & {S}_{14} \\ {S}_{21} & {S}_{22} & {S}_{23} & {S}_{24} \\ {S}_{31} & {S}_{32} & {S}_{33} & {S}_{34} \\ {S}_{41} & {S}_{42} & {S}_{43} & {S}_{44}\end{matrix} ) \qquad Equation 1$$

In Equation 1, component Sᵢⱼ of the S matrix represents the output voltage (or output power) of the j^{th} port with respect to the input voltage (or input power) at the i^{th} port. The Sᵢᵢ component of the S matrix represents the reflection parameter for each of the ports. The S₁₂ component of the S matrix represents the transmission parameter of port 2 with respect to port 1 and the S₃₄ component represents the transmission parameter of port 4 with respect to port 3. The $13 component of the S matrix represents the near-end crosstalk (NEXT) parameter of port 3 with respect to port 1 and the S₂₄ component represents the NEXT parameter of port 4 with respect to port 2. The S₁₄ component of the S matrix represents the far-end crosstalk (FEXT) parameter of port 4 with respect to port 1 and the S₂₃ component represents the FEXT parameter of port 3 with respect to port 2.

In some embodiments, the S matrix representing the S parameters may be considered as a symmetric matrix. Therefore, as described next, the prediction network 130 may predict the entire S parameter matrix based on the diagonal components and the upper triangular part of the S matrix as above (the part above the diagonal).

For example, the prediction network 130 may infer the port1-port1 reflection parameter (S₁₁) based on the representation vector corresponding to the segment connected to port 1 of the first component. Alternatively, the prediction network 130 may infer the port1-port2 transmission parameter (S₁₂) based on the representation vector corresponding to the segment connected to port 1 of the first component and the representation vector corresponding to the segment connected to port 2 of the second component. Alternatively, the prediction network 130 may infer the port1-port3 near-end crosstalk parameter (S₁₃) based on the representation vector corresponding to the segment connected to port 1 of the first component and the representation vector corresponding to the segment connected to port 3 of the first component. Alternatively, the prediction network 130 may infer the port1-port4 far-end crosstalk parameter (S₁₄) based on the representation vector corresponding to the segment connected to port 1 of the first component and the representation vector corresponding to the segment connected to port 4 of the second component.

Afterwards, the modeling device 100 may transmit a prediction result of the frequency characteristics of the substrate to the simulator 200. To that end, in some embodiments, the modeling device 100 may generate/predict graph images (or mappings, functions, etc.) of four S parameters (discussed next) as the frequency characteristics of the substrate. The graph images (mappings, functions, etc.) for the S parameters may be transmitted to the simulator 200; the simulator 200 may use the graph images as the frequency characteristics of the substrate for simulation.

The four graph images, for example, may respectively correspond to the reflection parameter, the transmission parameter, the near-end crosstalk parameter, and the far-end crosstalk parameter, respectively (in some embodiments, there may be more than one graph image of a given parameter type). The simulator 200 may model the substrate based on the predicted frequency characteristics of the substrate and may use the thus-configured substrate model to analyze the signal integrity of a signal transmitted/received in the substrate.

As described above, the modeling device 100 according to one or more embodiments may quickly and accurately predict S parameters of a substrate by transforming the substrate into a graph and generating embeddings representing the substrate from the transformed graph using at least one neural network. The simulator 200 may quickly and accurately perform simulation of a channel between driver and receiver based on the S parameters of the substrate predicted quickly and accurately by the modeling device 100.

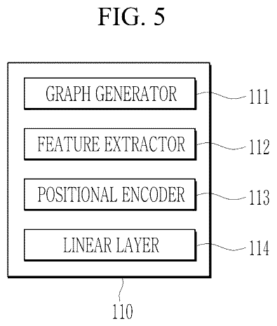

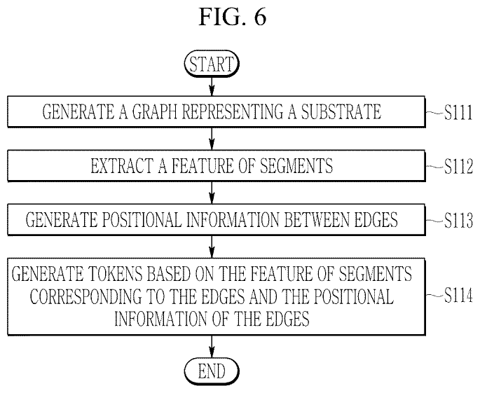

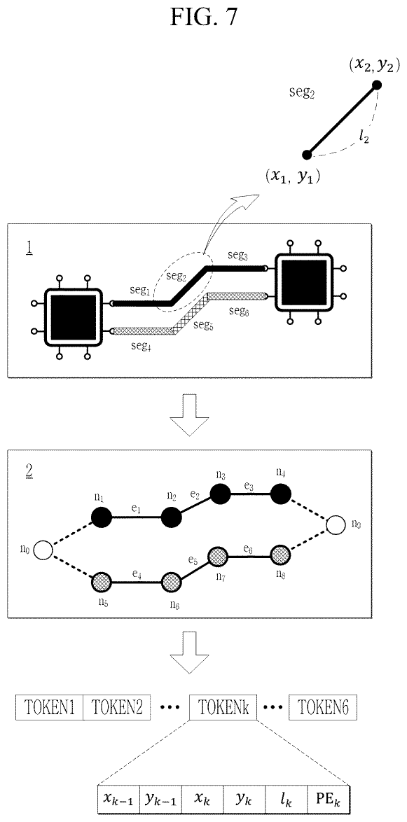

FIG. 5 illustrates a graph tokenizer according to one or more embodiments, FIG. 6 illustrates a method for generating a graph representing a trace and tokenizing the generated graph according to one or more embodiments, and FIG. 7 illustrates generating a graph representing a trace according to one or more embodiments and tokenizing the generated graph.

Referring to FIG. 5, a graph tokenizer 110 according to one or more embodiments may include a graph generator 111, a feature extractor 112, a positional encoder 113, and a linear layer 114.

Referring to FIGS. 5 to 7, the graph generator 111 of the graph tokenizer 110 may generate, as non-limiting examples, a graph 2 (FIG. 7) representing a 4-port network 1 (FIG. 7) from trace data of a substrate S111 (the upper part of FIG. 7 depicts an example of the segment 2 having a start point, an end point, and a length; the start point, end point, and length of a segment being expressible as trace data is depicted in FIG. 4). Referring to FIG. 7, the graph generator 111 may transform the 4-port network 1 consisting of a first component and a second component on the substrate and two traces connecting the first component and the second component into the graph 2. Each trace may include three segments.

In FIG. 7, seg1, seg2, and seg3 are included in the first trace and seg4, seg5, and seg6 are included in the second trace. For example, coordinates of a start point of the second segment seg2 in FIG. 7 may be (x₁,y₁), coordinates of an end point of the second segment seg2 may be (x₂, y₂), and the length of the second segment seg2 may be 12. As explained above, the coordinates of the start point of the kth segment may be the same as the coordinates of the end point of the (k−1)th segment.

In some embodiments, the graph tokenizer 110 may generate the graph 2 corresponding to the 4-port network 1 by matching the segments in the trace to edges of the graph 2 and connecting the edges and nodes at both ends of the edges to each other.

Referring to FIG. 7, the graph tokenizer 110 generates six edges having a one-to-one correspondence relationship with respective segments in the trace, generates nodes at both ends of each edge, and generates dummy nodes (dummy nodes) (n0 and n9) corresponding to each component of the 4-port network 1. In the graph 2, edges connected to dummy nodes are indicated by dotted lines, indicating that they are the edges that are not generated as tokens. Since a loop may correspond to a short circuit in the circuit on the substrate, the graph tokenizer 110 may be configured to avoid generating any loops on the graph 2.

Referring to FIGS. 5 and 6, at step S112, the feature extractor 112 of graph tokenizer 110 may extract features of the segments from the trace data of the substrate. In some embodiments, the feature extractor 112 may extract from the trace coordinate information and length information of each segment (which serve as the features of the segments). The feature extractor 112 may obtain coordinate information of both ends of the segment from the trace data and calculate length information of the segment from the coordinate information of both ends of the segment.

Referring to FIGS. 5 to 7, at step S113, the positional encoder 113 of the graph tokenizer 110 may perform positional encoding on the edges corresponding to the trace to generate positional information between the edges (e.g., positions of nodes). The positional information may represent the positional relationship between the edges in the graph 2. The positional encoder 113 may represent the position of an edge through its relationship with the neighboring edges by performing the positional encoding. For example, the order of tokens may indicate their relationships. For example, two adjacent tokens may share a start/end point.

In some embodiments, the positional encoder 113 may perform the positional encoding for the edges based on a Laplacian matrix (L) for the graph 2, but the present disclosure is not limited thereto, and the positional encoding may be performed using various methods other than the method using the Laplacian matrix.

In some embodiments, the positional encoder 113 may generate a Laplacian matrix using a degree matrix D and an adjacency matrix A. Equation 2 represents the degree matrix D of the graph 2 and the adjacency matrix A of the graph 2.

$$D = ( \begin{matrix}2 & 0 & 0 & 0 & 0 & 0 & 0 & 0 & 0 & 0 \\ 0 & 2 & 0 & 0 & 0 & 0 & 0 & 0 & 0 & 0 \\ 0 & 0 & 2 & 0 & 0 & 0 & 0 & 0 & 0 & 0 \\ 0 & 0 & 0 & 2 & 0 & 0 & 0 & 0 & 0 & 0 \\ 0 & 0 & 0 & 0 & 2 & 0 & 0 & 0 & 0 & 0 \\ 0 & 0 & 0 & 0 & 0 & 2 & 0 & 0 & 0 & 0 \\ 0 & 0 & 0 & 0 & 0 & 0 & 2 & 0 & 0 & 0 \\ 0 & 0 & 0 & 0 & 0 & 0 & 0 & 2 & 0 & 0 \\ 0 & 0 & 0 & 0 & 0 & 0 & 0 & 0 & 2 & 0 \\ 0 & 0 & 0 & 0 & 0 & 0 & 0 & 0 & 0 & 2\end{matrix} ) \qquad Equation 2$$

$$A = ( \begin{matrix}0 & 1 & 0 & 0 & 0 & 1 & 0 & 0 & 0 & 0 \\ 1 & 0 & 1 & 0 & 0 & 0 & 0 & 0 & 0 & 0 \\ 0 & 1 & 0 & 1 & 0 & 0 & 0 & 0 & 0 & 0 \\ 0 & 0 & 1 & 0 & 1 & 0 & 0 & 0 & 0 & 0 \\ 0 & 0 & 0 & 1 & 0 & 0 & 0 & 0 & 0 & 1 \\ 1 & 0 & 0 & 0 & 0 & 0 & 1 & 0 & 0 & 0 \\ 0 & 0 & 0 & 0 & 0 & 1 & 0 & 1 & 0 & 0 \\ 0 & 0 & 0 & 0 & 0 & 0 & 1 & 0 & 1 & 0 \\ 0 & 0 & 0 & 0 & 0 & 0 & 0 & 1 & 0 & 1 \\ 0 & 0 & 0 & 0 & 1 & 0 & 0 & 0 & 1 & 0\end{matrix} ) \qquad Equation 3$$

Afterwards, the positional encoder 113 may calculate the Laplacian matrix based on the degree matrix and adjacency matrix of the graph 2 as in Equation 4.

$$L = D - A = ( \begin{matrix}2 & - 1 & 0 & 0 & 0 & - 1 & 0 & 0 & 0 & 0 \\ - 1 & 2 & - 1 & 0 & 0 & 0 & 0 & 0 & 0 & 0 \\ 0 & - 1 & 2 & - 1 & 0 & 0 & 0 & 0 & 0 & 0 \\ 0 & 0 & - 1 & 2 & - 1 & 0 & 0 & 0 & 0 & 0 \\ 0 & 0 & 0 & - 1 & 2 & 0 & 0 & 0 & 0 & - 1 \\ - 1 & 0 & 0 & 0 & 0 & 2 & - 1 & 0 & 0 & 0 \\ 0 & 0 & 0 & 0 & 0 & - 1 & 2 & - 1 & 0 & 0 \\ 0 & 0 & 0 & 0 & 0 & 0 & - 1 & 2 & - 1 & 0 \\ 0 & 0 & 0 & 0 & 0 & 0 & 0 & - 1 & 2 & - 1 \\ 0 & 0 & 0 & 0 & - 1 & 0 & 0 & 0 & - 1 & 2\end{matrix} ) \qquad Equation 4$$

In some embodiments, the positional encoder 113 may perform the positional encoding of the edges within the graph using eigenvectors of the Laplacian matrix. For example, the positional encoder 113 may generate the positional information of an edge by adding eigenvectors corresponding to nodes at both ends of the edge. The eigenvectors of the Laplacian matrix may correspond to each node of the graph 2.

The eigenvectors v₁ to v₈ of the Laplacian matrix corresponding to the nodes n₁ to n₈ of the graph 2 in FIG. 7 are as shown in Equations 5 to 12 below.

$${v}_{1} = ( \begin{matrix}- 1 \\ 1 \\ - 1 \\ 1 \\ - 1 \\ 1 \\ - 1 \\ 1 \\ - 1 \\ 1\end{matrix} ) \qquad Equation 5$$

$${v}_{2} = ( \begin{matrix}0 \\ - 1 \\ \frac{\sqrt{5} - 1}{2} \\ \frac{\sqrt{5} - 1}{2} \\ - 1 \\ 1 \\ \frac{\sqrt{5} - 1}{2} \\ \frac{\sqrt{5} - 1}{2} \\ 1 \\ 0\end{matrix} ) \qquad Equation 6$$

$${v}_{3} = ( \begin{matrix}0 \\ 1 \\ \frac{\sqrt{5} - 1}{2} \\ \frac{- \sqrt{5} - 1}{2} \\ - 1 \\ - 1 \\ \frac{- \sqrt{5} + 1}{2} \\ \frac{\sqrt{5} - 1}{2} \\ 1 \\ 0\end{matrix} ) \qquad Equation 7$$

$${v}_{4} = ( \begin{matrix}0 \\ 1 \\ \frac{- \sqrt{5} - 1}{2} \\ \frac{\sqrt{5} + 1}{2} \\ - 1 \\ - 1 \\ \frac{\sqrt{5} + 1}{2} \\ \frac{- \sqrt{5} - 1}{2} \\ 1 \\ 0\end{matrix} ) \qquad Equation 8$$

$${v}_{5} = ( \begin{matrix}0 \\ - 1 \\ \frac{- \sqrt{5} - 1}{2} \\ \frac{- \sqrt{5} - 1}{2} \\ - 1 \\ 1 \\ \frac{\sqrt{5} + 1}{2} \\ \frac{\sqrt{5} + 1}{2} \\ 1 \\ 0\end{matrix} ) \qquad Equation 9$$

$${v}_{6} = ( \begin{matrix}- 1 \\ 0 \\ 1 \\ \frac{- \sqrt{5} + 1}{2} \\ \frac{- \sqrt{5} + 1}{2} \\ \frac{\sqrt{5} - 1}{2} \\ \frac{\sqrt{5} - 1}{2} \\ - 1 \\ 0 \\ 1\end{matrix} ) \qquad Equation 10$$

$${v}_{7} = ( \begin{matrix}- 1 \\ 0 \\ 1 \\ \frac{- \sqrt{5} + 1}{2} \\ \frac{- \sqrt{5} + 1}{2} \\ \frac{\sqrt{5} - 1}{2} \\ \frac{\sqrt{5} - 1}{2} \\ - 1 \\ 0 \\ 1\end{matrix} ) \qquad Equation 11$$

$${v}_{8} = ( \begin{matrix}1 \\ 0 \\ - 1 \\ \frac{\sqrt{5} + 1}{2} \\ \frac{- \sqrt{5} - 1}{2} \\ \frac{- \sqrt{5} - 1}{2} \\ \frac{\sqrt{5} + 1}{2} \\ - 1 \\ 0 \\ 1\end{matrix} ) \qquad Equation 12$$

Additionally, the positional information PEk of the kth edge may be determined as the sum of two eigenvectors corresponding to each end node of the kth edge.

In the graph 2 of FIG. 7, the positional information PE1 to PE6 of the edge e1 to e6 may be determined by the sum of the eigenvectors corresponding to the nodes at both ends of the edge. For example, the positional relationship information PE1 of the edge e1 may be determined by the vector sum of eigenvectors v1 and v2 corresponding to the two end nodes n1 and n2 of the edge e1, respectively.

The positional information PE1 to PE6 is as follows: Equations 13 to 18.

$${PE}_{1} = {v}_{1} + {v}_{2} = ( \begin{matrix}- 1 \\ 0 \\ \frac{\sqrt{5} - 3}{2} \\ \frac{\sqrt{5} + 1}{2} \\ - 2 \\ 2 \\ \frac{- \sqrt{5} - 1}{2} \\ \frac{- \sqrt{5} + 3}{2} \\ 0 \\ 1\end{matrix} ) \qquad Equation 13$$

$${PE}_{2} = {v}_{2} + {v}_{3} = ( \begin{matrix}0 \\ 0 \\ \sqrt{5} - 1 \\ 0 \\ - 2 \\ 0 \\ - \sqrt{5} + 1 \\ \frac{- \sqrt{5} + 3}{0} \\ 2 \\ 0\end{matrix} ) \qquad Equation 14$$

$${PE}_{3} = {v}_{3} + {v}_{4} = ( \begin{matrix}0 \\ 2 \\ - 1 \\ 1 \\ - 2 \\ - 2 \\ 1 \\ - 1 \\ 2 \\ 0\end{matrix} ) \qquad Equation 15$$

$${PE}_{4} = {v}_{5} + {v}_{6} = ( \begin{matrix}- 1 \\ - 1 \\ \frac{- \sqrt{5} + 1}{2} \\ - \sqrt{5} \\ \frac{- \sqrt{5} - 1}{2} \\ \frac{\sqrt{5} + 1}{2} \\ - \sqrt{5} \\ \frac{- \sqrt{5} - 1}{2} \\ 1 \\ 1\end{matrix} ) \qquad Equation 16$$

$${PE}_{5} = {v}_{6} + {v}_{7} = ( \begin{matrix}0 \\ 0 \\ 0 \\ - \sqrt{5} + 1 \\ 0 \\ \sqrt{5} - 1 \\ 0 \\ - 2 \\ 0 \\ 2\end{matrix} ) \qquad Equation 17$$

$${PE}_{6} = {v}_{7} + {v}_{8} = ( \begin{matrix}2 \\ 0 \\ - 2 \\ 1 \\ - 1 \\ - 1 \\ 1 \\ - 2 \\ 0 \\ 2\end{matrix} ) \qquad Equation 18$$

Referring to FIG. 7, the features of the segments extracted by the feature extractor 112 and the positional information between the edges encoded by the positional encoder 113 may be concatenated and passed on to the linear layer 114 of the graph tokenizer 110.

Referring to FIGS. 5 to 7, the linear layer 114 may generate token representing respective edges by linearizing the features of the segments corresponding to the edges of the graph 2 and the positional information of the corresponding edges S114. The linear layer 114 of the graph tokenizer 110 may be a neural network trained to tokenize features of segments (e.g., corresponding to the edges and the positional information of the corresponding edges) into corresponding tokens. The linear layer 114 may tokenize the features of the segments being processed into their respectively corresponding tokens.

In some embodiments, the features of a segment extracted by the feature extractor 112 may be included in the corresponding token as geometrical information of the segment. That is, since the features of the segments are included in the tokens, the mutual influence between the segments within the trace may be reflected in the tokens.

In some embodiments, the positional information encoded by the positional encoder 113 may be included in the token as topological information of the segment. That is, since the positional information is included in the token, the connection status between the edges in the graph generated from the trace data of the substrate may be reflected in the tokens.

In some embodiments, the linear layer 114 may generate the token corresponding to an edge by performing a linear projection on the features of the corresponding segment and the positional information. For example, when α edges are included in the example of graph 2, a tokens respectively corresponding to the α edges may be generated by linear layer 114, and the α tokens may form a sequence of tokens for the example 4-port network. When each token is a vector with β elements, the sequence of tokens may be represented by an α×β matrix. Since each edge has a one-to-one correspondence relationship with one segment, each token in the sequence of tokens may represent a corresponding segment of the trace, and each of the segments of the trace may be represented by a token.

Referring to FIG. 7 (bottom third), the features of the segment included in token k (“TOKENk” in the figure, which is representative of any token) may include coordinate information of the kth segment (its start point coordinates xₖ₋₁ and yₖ₋₁, and endpoint coordinates xₖ, and yₖ) and positional information (PER) of the kth edge corresponding to the kth segment.

Afterwards, the sequence of tokens generated from the graph 2, for example, may be input to the encoder 120 and may be transformed into a set of representation vectors representing the trace by the encoder 120.

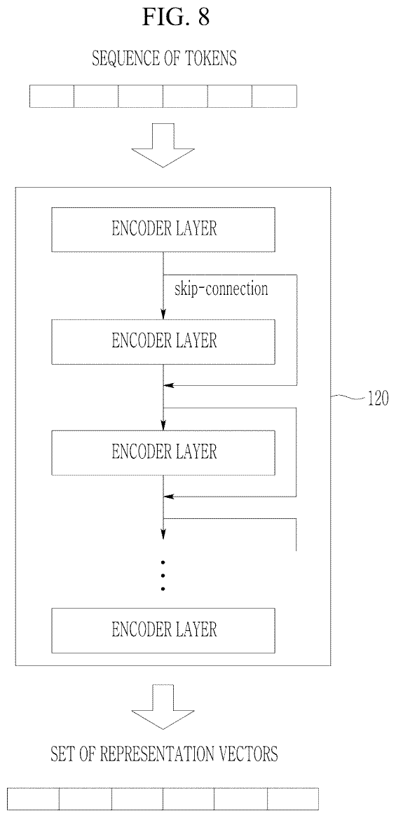

FIG. 8 illustrates the structure of an encoder according to one or more embodiments.

Referring to FIG. 8, the encoder 120 may generate a set of representation vectors of a trace by passing a sequence of tokens generated by the graph tokenizer 110 through encoder layers. In some embodiments, the encoder 120 may be a trained neural network that encodes the tokens of the graph into the representation vectors.

In some embodiments, each of the encoder layers may output a vector having the same dimension as the input vector. For example, when the sequence of tokens input to the plurality of encoder layers is an α×β matrix, each encoder layer may output an α×β matrix. Therefore, the set of representation vectors output by the encoder 120 may also be in the form of an α×β matrix.

In some embodiments, each representation vector in the set of representation vectors of the traces generated by the encoder 120 may correspond to each token. Since each token represents each segment of the trace, respectively, each representation vector in the set of representation vectors generated by the encoder 120 may be an embedding of the corresponding segment of the trace. Additionally, within the set of representation vectors, the representation vector corresponding to a segment connected to a port may be a vector representing that port.

As described above, the graph tokenizer 110 generates a representation of the trace (from the graph of the substrate) by tokenizing the graph, and the encoder 120 encodes the tokens into respective representation vectors that represent the tokenized graph, so that embeddings for modeling the substrate may be generated.

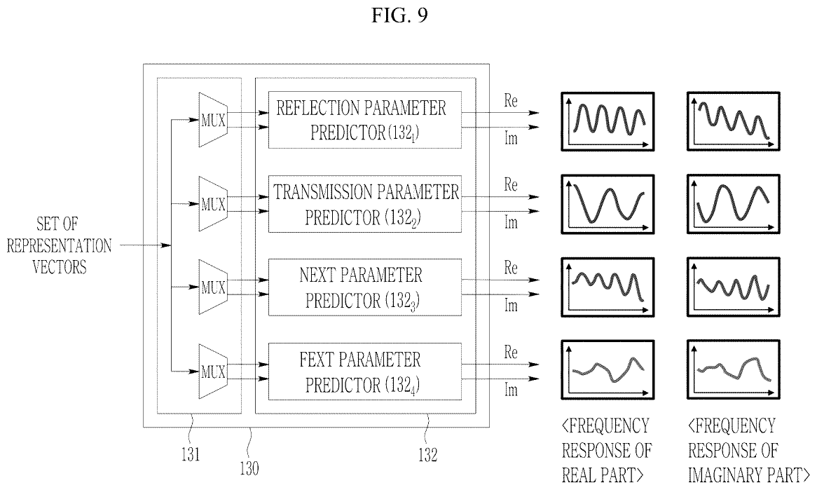

FIG. 9 illustrates the structure of a prediction network according to one or more embodiments.

Referring to FIG. 9, the prediction network 130 may include a selector 131 and parameter predictors 132.

In some embodiments, the predictors 132 of the prediction network 130 may be trained neural networks. Each parameter predictor 132 neural network may generate graph images representing frequency responses of a real part and imaginary part from the representation vectors selected by the selectors 131, respectively. The prediction network 130 may perform decoding to generate the graph images from representation vectors using the parameter predictors 132.

In some embodiments, the selector 131 may determine, among the set of representation vectors of the trace, which of the representation vectors are to be processed by which of parameter predictors 132. For example, the selector 131 may multiplex the selected representation vectors, and transfer the selected representation vectors to the corresponding parameter predictors 132, for example, according to the types of the representation vectors (e.g., reflection, transmission, NEXT, or FEXT).

For example, the selector 131 may select a first representation vector representing a first segment connected to port 1 of a first component from a set of representation vectors and transfer the selected representation vector to a reflection parameter predictor 1321. As described above, the representation vector corresponding to a segment connected to a specific port is a vector representing that port, so the selector can transfer the vector required for the predictor according to the type of each predictor. The representation vector corresponding to which segment is required for each type of the predictor is described further above.

Alternatively or additionally, the selector 131 may select (i) the first representation vector which represents the first segment connected to port 1 of the first component and (ii) a second representation vector which represents a second segment connected to port 2 of a second component from the set of representation vectors, and transmit the two selected representation vectors to a transmission parameter predictor 1322.

Alternatively or additionally, the selector 131 may select (i) the first representation vector which represents the first segment connected to port 1 of the first component and (ii) a third representation vector representing a third segment connected to port 3 of the first component from the set of representation vectors, and transmit the two selected representation vectors to the NEXT parameter predictor 1323.

Alternatively or additionally, the selector 131 may select (i) the first representation vector representing the first segment connected to port 1 of the first component and (ii) a fourth representation vector representing a fourth segment connected to port 4 of the second component from the set of representation vectors, and transmit the two selected representation vectors to the FEXT parameter predictor 1324.

In some embodiments, the parameter predictors 132 may generate graphs (e.g., mappings, functions, tables, or any form of information relating frequency response) of frequency responses corresponding to S parameters of the 4-port network based on selected representation vectors (S parameters may represent reflection and transmission characteristics of a signal and are usually expressed in complex form (include a real part and an imaginary part)). The parameter predictors 132 may generate a graph of the frequency response of the real part and a graph of the frequency response of the imaginary part, respectively.

The parameter predictors 132 of the prediction network 130 may each be a trained neural network that outputs graph images (or matrices, data volumes, etc.) of frequency responses corresponding to each parameter (e.g., FEXT, NEXT, reflection, etc.) of the 4-port network by using at least one representation vector corresponding to a segment connected to a port of a component of the 4-port network as an input. An AI model used as the parameter predictor 132 may be a generative adversarial network (GAN), an autoencoder, a transformer-based model, etc. Note that, as described above, the parameter predictor 132 may be trained to generate a graph image from an input vector. The AI model used as the parameter predictor 132 may be a Generative Adversarial Network (GAN), an autoencoder, a transformer-based model, etc.

Referring to FIG. 9, the reflection parameter predictor 1321 may output a first graph image corresponding to the reflection parameter of the 4-port network by using the first representation vector corresponding to the first segment connected to port 1 of the first component as an input.

Referring to FIG. 9, the transmission parameter predictor 1322 may output a second graph image corresponding to the transmission parameters of the 4-port network by using the first representation vector corresponding to the first segment connected to port 1 of the first component and the second representation vector corresponding to the second segment connected to port 2 of the second component as an input.

Referring to FIG. 9, the NEXT parameter predictor 1323 may output a third graph image corresponding to the NEXT parameter of the 4-port network by using the first representation vector corresponding to the first segment connected to port 1 of the first component and the third representation vector corresponding to the third segment connected to port 3 of the first component as an input.

Referring to FIG. 9, the FEXT parameter predictor 1324 may output a fourth graph image corresponding to the FEXT parameter of the 4-port network by using the first representation vector corresponding to the first segment connected to port 1 of the first component and the fourth representation vector corresponding to the fourth segment connected to port 4 of the second component as an input.

In some embodiments, a multi-task learning technique may be used for efficient learning among the reflection parameter predictors 1321, the transmission parameter predictor 1322, the NEXT parameter predictor 1323, and the FEXT parameter predictor 1324 included in the plurality of parameter predictors 132. That is, each of the parameter predictors 132 may perform the multi-task learning by sharing the same representation vector (e.g., the first representation vector corresponding to the first segment connected to port 1 of the first component) as an input for generating the graph images.

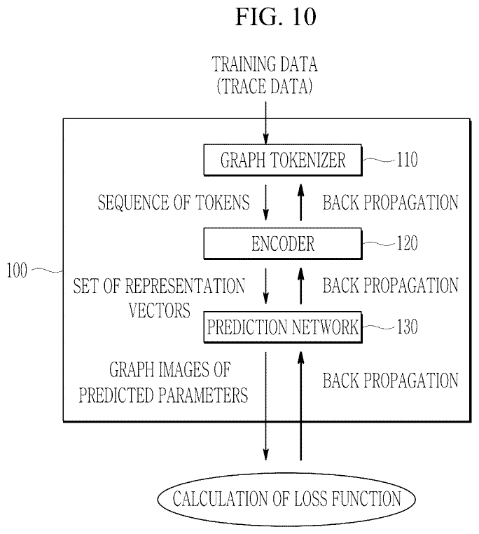

FIG. 10 illustrates the training steps of a modeling device according to one or more embodiments.

In some embodiments, the graph tokenizer 110 of the modeling device 100 may be trained to tokenize a graph generated from trace data of a substrate. The encoder 120 of the modeling device 100 may be trained to output representation vectors that represent the trace of the substrate based on a sequence of tokens generated by the graph tokenizer 110. Afterwards, the prediction network 130 may be trained to output graph images corresponding to the S parameters of the 4-port network by inferring the graph images from the representation vectors representing the trace of the substrate as an input.

Referring to FIG. 10, when the trace data of the labeled substrate is input as training data to the modeling device 100, the graph tokenizer 110 of the modeling device 100 may generate a graph based on the trace data and tokenize generated graph into a sequence of tokens. The labeled substrate is a substrate of which frequency characteristics have been determined in advance through analysis on the frequency characteristics for substrates by an analysis program (such as the SIWave), for example, or from any other suitable source that can serve as ground truth data. That is to say, a labeled substrate may be data describing a substrate (e.g., trace data) processable (subject to inference) by the neural network models of the modeling device 100. The trace data of the labeled substrate may be matched in advance with the ground truth analysis result of the frequency characteristics of the labeled substrate. For example, the labeled graph image may show the S parameters of the 4-port network on the labeled substrate. In some embodiments, neural networks of the modeling device 100 may be trained in a supervised learning manner.

The encoder 120 may generate a set of representation vectors representing the trace by embedding the sequence of tokens. The prediction network 130 may predict the S parameters of the 4-port network including the trace by using the set of representation vectors of the trace as an input. That is, the prediction network 130 may output graph images of predicted S parameters from the input set of representation vectors.

Referring to FIG. 10, a loss function may be calculated based on a difference between the graph images (or the like) of the predicted S parameters and a labeled graph image of the trace data. The labeled graph image of the trace data input to the modeling device 100 for training may be determined in advance by an analysis result on a substrate (which may then be considered to be a labeled substrate, i.e., is labeled/associated with the result).

Referring to FIG. 10, the result of the loss function calculated based on the difference between the graph images of the predicted S parameters and the labeled graph images of the trace data input to the modeling device 100 for training may be backpropagated in the order of the prediction network 130, the encoder 120, and the graph tokenizer 110 of the modeling device 100.

In some embodiments, weight values and parameters of the neural network of the prediction network 130, which is used to generate the graph image from the representation vectors, may be updated by the backpropagated calculation result of the loss function.

Through this, the prediction network 130 may be trained to accurately generate the graph images of the S parameters from the representation vectors. Additionally, weight values and parameters of the encoder 120 may be updated based on the calculation results of the loss function backpropagated from the prediction network 130. The skip connection of the encoder 120 may be used to solve the slope disappearance problem of the backpropagation.

Further, the encoder 120 may be trained so that the representation vector corresponding to each segment may well represent each port of the 4-port network. Additionally, weight values and parameters of the linear layer 114 of the graph tokenizer 110 may be updated by the calculation result of the loss function backpropagated from the encoder 120. This enables the linear layer 114 of the graph tokenizer 110 to generate the tokens that more accurately reflect the influence between the segments and the connectivity of the graph generated from trace data.

In some embodiments, the modeling device 100 may be updated multiple times using pairs of the trace data for training and the labeled graph images corresponding to the trace data (i.e., trace-graph pairs). For example, when the calculation result of the loss function between the graph images of the predicted parameters and the labeled graph image satisfies a predetermined criteria, training of modeling device 100 may be terminated. Alternatively, when the update of the modeling device 100 based on the loss function based on the graph images of the predicted parameters and the labeled graph image is performed a predetermined number of times, the training of the modeling device 100 may be terminated.

Based on the trace data of the substrate, the substrate is changed to a graph and an embedding representing the substrate is generated from the graph using the neural network, so that the S parameter of the substrate can be predicted quickly and accurately despite the increasing design complexity of the substrate and the expanding frequency range of the analysis target. Since the predicted S parameter is used to model the channel between the driver-receiver, based on the S parameter of the substrate being predicted quickly, channel simulation can be performed quickly and problems in the designed substrate can be fixed quickly.

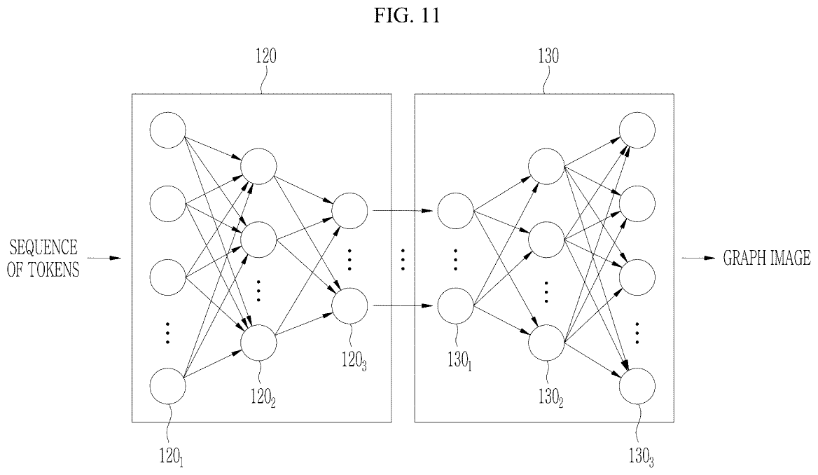

FIG. 11 illustrates a neural network structure of the encoder and prediction network according to one or more embodiments.

Referring to FIG. 11, the encoder 120 and the prediction network 130 according to one or more embodiments may have a neural network (NN) structure including input layers 1201 and 1301, hidden layers 1202 and 1302, and output layers 1203 and 1303, respectively. In some embodiments, the encoder 120 may have an encoder structure that compresses (encodes) features of the input sequence of tokens into a representation vectors.

In addition, the prediction network 130 may have a decoder structure that generates graph images of predicted parameters from the representation vectors. The input layers 1201 and 1301, hidden layers 1202 and 1302, and output layers 1203 and 1303 of the encoder 120 and the prediction network 130 may each include a respective set of nodes and the strength of connections between each node may correspond to a weight (a connection weight). The nodes included in the input layers 1201 and 1301, the hidden layers 1202 and 1302, and the output layers 1203 and 1303 may be connected to each other with a fully connected type of architecture.

The number of parameters (a weight and a bias) may be equal to the number of connections in the neural network 1100. The input layers 1201 and 1301 may include input nodes, and the number of input nodes may correspond to the number of independent input variables.

For training the encoder 120, a set of trace data may be input to the input layer 1201. When the trace data of an inference target is input into the input layer 1201 of the encoder 120, the graph images of the predicted parameters may be output as the inference result from the output layer 1303 of the trained prediction network 130.

The hidden layers 1202 and 1302 may be positioned between the input layers 1201 and 1301 and output layers 1203 and 1303 and may include at least one hidden layer. The output layers 1203 and 1303 may include at least one output node. An activation function may be used in the hidden layers 1202 and 1302 and output layers 1203 and 1303 to determine node outputs/activations.

In some embodiments, the encoder 120 and the prediction network 130 may be trained by updating the weights and/or parameters of the hidden nodes included in the hidden layers 1202 and 1302.

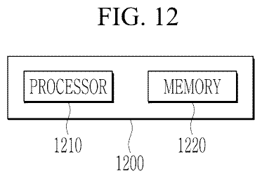

FIG. 12 illustrates a modeling device according to another embodiment. The modeling device may be implemented as a computer system, for example, as a computer-readable medium (but not a signal per se).

Referring to FIG. 12, the computer system 1200 may include at least one processor 1210 and at least one memory 1220. The memory 1220 may be connected to the processor 1210 and may store instructions causing the processor 1210 to perform a plurality of steps or at least one program described above.

The processor 1210 may implement the function, process, or method proposed in the embodiment. An operation of the computer system 1200 may be implemented by the processor 1210. At least one processor 1210 may include at least one of a GPU, a CPU, an NPU, FPGA, or DSP. In practice the processor 1210, may be one or more processors of one or more types. When the operation of the computer system 1200 is implemented by at least one processor 1210, each work may be divided according to the load among at least one processor 1210. For example, when one processor is a CPU, another processor may be any of a GPU, NPU, FPGA, or DSP.

In the embodiments of the present disclosure, the at least one memory 1220 may be positioned internally or externally to the processor and the memory may be connected to the processor via a variety of known means. The memory 1220 is a type of storage medium that may be volatile or non-volatile. For example, the memory 1220 may include a read-only memory (ROM) or a random access memory (RAM).

In another way, some functions (e.g., training the yield predicting model and/or the path generating model, inference by the yield predicting model and/or the path generating model) of the yield predicting device may be provided by a neuromorphic chip including neurons, synapses, and inter-neuron connection modules. The neuromorphic chip is a computer device simulating biological neural system structures, and may perform neural network operations.

Meanwhile, embodiments are not implemented only through the devices and/or methods described so far, but may also be implemented through a program that realizes a function corresponding to the configuration of embodiments or a recording medium in which the program is recorded, and such implementation can be easily implemented by a person skilled in the art to which the present description belongs based on the description of the embodiments described above. Specifically, a method according to the embodiment (e.g., an image preprocessing method, etc.) can be implemented in the form of a program instruction that can be performed through various computer means and recorded on a computer-readable medium. The computer-readable medium may include program instructions, data files, data structures, etc., alone or in combination. The program instructions recorded on the computer-readable medium may be specially designed and configured for embodiment, or may be known and available to those skilled in the art of computer software. A computer-readable recording medium may include a hardware device configured to store and execute program instructions. For example, the computer-readable recording medium can be magnetic media such as hard disks, floppy disks, and magnetic tape, optical media such as CD-ROMs and DVDs, magneto-optical media such as floptical disks, ROM, RAM, flash memory, etc. Program instructions may include machine language code, such as that produced by a compiler, as well as high-level language code that can be executed by a computer through an interpreter, etc. Although the embodiments have been described in detail above, the scope of this disclosure is not limited thereto, and various modifications and improvements of a person of an ordinary skill in the art utilizing the basic concepts defined in the following claims also fall within the scope of this disclosure.

The computing apparatuses, the electronic devices, the processors, the memories, the image sensors, the displays, the information output system and hardware, the storage devices, and other apparatuses, devices, units, modules, and components described herein with respect to FIGS. 1-11 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-11 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An apparatus for determining frequency characteristics of a substrate, the apparatus comprising:
one or more processors and a memory, wherein the memory stores instructions causing the one or more processors to perform a process comprising:
transforming a trace of the substrate to a graph and tokenizing the graph into tokens;
generating representation vectors from the tokens; and
determining the frequency characteristics based on the representation vectors.

2. The apparatus of claim 1, wherein the transforming the trace of the substrate to the graph and tokenizing the graph into tokens comprises:
generating the graph to represent a 4-port network included in the substrate; and
tokenizing the graph into a sequence of the tokens.

3. The apparatus of claim 2, wherein:
the 4-port network includes two components and the trace connecting the two components, and
the generating the graph representing the 4-port network included in the substrate comprises
generating edges respectively corresponding to segments included in the trace and connecting ends of the edges at corresponding nodes.

4. The apparatus of claim 3, wherein the tokenizing the graph into the sequence of tokens comprises:
extracting features of the segments from trace data of the substrate;
generating positional information by performing positional encoding on the edges; and
generating the tokens respectively corresponding to the edges based on the features and positional information of the corresponding segments.

5. The apparatus of claim 4, wherein the generating the tokens respectively corresponding to the edges based on the features of the segment and the positional information comprises:
performing linear projection on the features and positional information of the segments using a linear layer of a neural network.

6. The apparatus of claim 4, wherein each segment comprises corresponding coordinate information thereof the segment and length information thereof.

7. The apparatus of claim 1, wherein the determining the frequency characteristics based on the representation vectors comprises:
predicting scattering parameters of a 4-port network included in the substrate as the frequency characteristics of the substrate.

8. The apparatus of claim 7, wherein the predicting the scattering parameters of the 4-port network included in the substrate as the frequency characteristics of the substrate comprises:
predicting the scattering parameters by using representation vectors respectively corresponding to segments connected to each component of the 4-port network among segments included in the trace as an input.

9. The apparatus of claim 8, wherein the predicting the scattering parameters by using a representation vector corresponding to a segment connected to each component of the 4-port network among a plurality of segments included in the trace as an input comprises:
outputting a first graph image corresponding to a reflection parameter of the scattering parameters by using a first representation vector corresponding to a first segment connected to a first port of a first component of the 4-port network as a first input;
outputting a second graph image corresponding to a transmission parameter of the scattering parameters by using a second representation vector corresponding to a second segment connected to a second port of a second component of the 4-port network as a second input;
outputting a third graph image corresponding to a near-end crosstalk parameter of the scattering parameters by using a third representation vector corresponding to a third segment connected to a third port of the first component of the 4-port network as a third input; or
outputting a fourth graph image corresponding to a far-end crosstalk parameter of the scattering parameters by using a fourth representation vector corresponding to a fourth segment connected to a fourth port of the second component of the 4-port network as a fourth input.

10. The apparatus of claim 9, wherein the process further comprises:
transferring one or more of the graph images to a simulator for signal integrity analysis of the substrate.

11. A method for predicting frequency characteristics of a substrate performed by one or more processors, the method comprising:
tokenizing a graph representing a trace of the substrate into a sequence of tokens;
generating a set of representation vectors by encoding the sequence of tokens; and
predicting the frequency characteristics based on the set of representation vectors.

12. The method of claim 11, wherein the tokenizing the graph representing the trace of the substrate into the sequence of tokens comprises:
generating geometrical information of segments included in the trace from trace data of the substrate;
generating topology information of the segments by performing positional encoding on edges in the graph; and
generating tokens corresponding to the edges based on the geometrical information and the topology information.

13. The method of claim 11, wherein the generating the set of representation vectors by encoding the sequence of tokens comprises:
encoding the sequence of tokens into the set of representation vectors through encoder layers of a neural network.

14. The method of claim 13, wherein:
the representation vectors in the set of representation vectors are embeddings of respective segments included in the trace, and
tokens included in the sequence of tokens respectively corresponds to the segments.

15. The method of claim 11, wherein
the predicting the frequency characteristics based on the set of representation vectors comprises
predicting scattering parameters of a 4-port network on or in the substrate as the frequency characteristics using a trained prediction network.

16. The method of claim 15, wherein the predicting scattering parameters of the 4-port network on or in the substrate as the frequency characteristics using the trained prediction network comprises:
inputting representation vectors corresponding to segments connected to each component of the 4-port network to the trained prediction network; and
predicting graph images respectively corresponding to each of a reflection parameter, a transmission parameter, a near-end crosstalk parameter, and a far-end crosstalk parameter of the scattering parameters using the trained prediction network.

17. The method of claim 16, further comprising:
transmitting predicted graph images respectively corresponding to the reflection parameter, the transmission parameter, the near-end crosstalk parameter; and the far-end crosstalk parameter to a simulator for signal integrity analysis of the substrate.

18. An apparatus for determining frequency characteristics of a substrate, the apparatus comprises:
one or more processors and a memory, wherein the memory stores instructions configured to cause the one or more processors to perform a process comprising:
transforming a trace of the substrate into a graph;
tokenizing the graph into a sequence of tokens using a linear layer of neural network;
generating a set of representation vectors from the sequence of tokens using an encoder of the neural network; and
using a prediction network to determine the frequency characteristics from the set of representation vectors by using a prediction network.

19. The apparatus of claim 18, wherein the process further comprises:
training the linear layer, the encoder, and the prediction network using trace data of a labeled substrate and a labeled graph image matched to the trace data,
wherein the labeled substrate is a substrate of which training frequency characteristics have been determined in advance as a ground truth.

20. The apparatus of claim 19, wherein the training the linear layer, the encoder, and the prediction network using trace data of the labeled substrate and graph images matched to the trace data comprises:
tokenizing a graph representing traces of the labeled substrate using the linear layer;
generating an embedding from tokenized graphs using the encoder;
predicting a training graph image of scattering parameters of the labeled substrate from the embedding using the prediction network; and
updating the linear layer, the encoder, and the prediction network based on calculation of a loss function using the predicted training graph image and the labeled graph image.
